(19) United States
(12) Patent Application Publication
(10) Pub. No.: US 2021/0206697 A1
(43) Pub. Date: Jul. 8, 2021

(54) Sn-Zn-O-BASED OXIDE SINTERED BODY AND METHOD FOR PRODUCING THE SAME

(71) Applicant: SUMITOMO METAL MINING CO., LTD., Tokyo (JP)

(72) Inventors: Makoto OZAWA, Ome-shi (JP); Shigeru IGARASHI, Ome-shi (JP); Isao ANDO, Ome-shi (JP)

(73) Assignee: Sumitomo Metal Mining Co., Ltd., Tokyo (JP)

(21) Appl. No.: 15/777,587

(22) PCT Filed: Sep. 20, 2016
(86) PCT No.: PCT/JP2016/077670

§ 371 Date: May 18, 2018

(30) Foreign Application Priority Data
Nov. 20, 2015 (JP) 2015-227722
Feb. 15, 2016 (JP) 2016-025680
Jun. 21, 2016 (JP) 2016-122320

(51) Int. Cl. C04B 35/49; C04B 35/488; C04B 35/626; C04B 35/632; C04B 35/64; H01B 1/08; H01B 13/34

(52) U.S. Cl. CPC C04B 35/49; C04B 2235/77; C04B 35/4885; C04B 35/6261; C04B 35/632; C04B 35/64; H01B 1/08; H01B 13/34; C04B 2235/3248; C04B 2235/3293; C04B 2235/3298; C04B 2235/3251; C04B 2235/3418; C04B 2235/3232; C04B 2235/3287; C04B 2235/3286; C04B 2235/3229; C04B 2235/3217; C04B 2235/3258; C04B 2235/3256; C04B 2235/604; C04B 2235/6567; C04B 2235/6585; C04B 35/488

(57) ABSTRACT

[Object] An object is to provide a Sn—Zn—O-based oxide sintered body which has a mechanical strength, a high density, and a low resistance characteristic and which is applied as a sputtering target, and a method for producing the same.

[Solving Means] In this oxide sintered body, Sn is contained with an atomic ratio of Sn/(Sn+Zn) being 0.1 or more and 0.9 or less, and a first additional element M is contained with an atomic ratio of M/(Sn+Zn+M+X) being 0.0001 or more and 0.04 or less relative to a total amount of all the metal elements, and a second additional element X is contained with an atomic ratio of X/(Sn+Zn+M+X) being 0.0001 or more and 0.1 or less relative to the total amount of all the metal elements, where the first additional element M is at least one selected from Si, Ti, Ge, In, Bi, Ce, Al, and Ga, and the second additional element X is at least one selected from Nb, Ta, W, and Mo, and a relative density of the sintered body is 90% or more and a specific electrical resistance of the sintered body is 1 Ω·cm or less.

### TECHNICAL FIELD

The present invention relates to a Sn—Zn—O-based oxide sintered body used as a sputtering target in the production of transparent conductive films applied to solar cells, liquid crystal surface elements, touch panels, and the like by a sputtering method such as direct-current sputtering or high-frequency sputtering. In particular, the present invention relates to a high density and low resistance Sn—Zn—O-based oxide sintered body which is resistant to e.g. breakage in the processing of the sintered body and to breakage and crack formation in the sputtering target during sputtering film formation, and a method for producing the same.

### BACKGROUND ART

Transparent conductive films, which have a high electrical conductivity and high transmittance in the visible light region, are used for solar cells, liquid crystal display elements, surface elements for organic electroluminescence, inorganic electroluminescence, etc., electrodes for touch panels, and the like, and also are used as heat ray reflection films for automobile windows or architecture, antistatic films, and various anti-fogging transparent heaters for freezer showcase and the like.

As the transparent conductive films, tin oxide (SnO₂) containing antimony or fluorine as a dopant, zinc oxide (ZnO) containing aluminum or gallium as a dopant, indium oxide (In₂O₃) containing tin as a dopant, and the like are known. In particular, indium oxide (In₂O₃) films containing tin as a dopant, i.e., In—Sn—O-based films, which are referred to as ITO (Indium tin oxide) films, are widely used because these films can be obtained easily as films having low resistance.

As a method for producing the transparent conductive films described above, a sputtering method such as direct-current sputtering or high-frequency sputtering is often used. The sputtering method is an effective method when a film is formed from a material having a low vapor pressure or when precise control of the film thickness is required, and is widely used in the industrial field, because the operation is very simple.

In this sputtering method, a sputtering target is used as a raw material of the thin film. The sputtering target is a solid containing a metal element which is to constitute the thin film to be formed. As the sputtering target, a sintered body of a metal, a metal oxide, a metal nitride, a metal carbide, or the like is used, or in some cases, a single crystal thereof is used. In the sputtering method, an apparatus having a vacuum chamber in which a substrate and a sputtering target can be placed is used, in general. After a substrate and a sputtering target are placed therein, the vacuum chamber is evacuated to high vacuum, and then the gas pressure inside the vacuum chamber is set to approximately 10 Pa or below by introducing a noble gas such as argon. Then, an argon plasma is generated by causing glow discharge between the substrate and the sputtering target where the substrate serves as an anode and the sputtering target serves as a cathode. The sputtering target serving as the cathode is bombarded with argon cations in the plasma, and constituent particles of the target ejected by the bombardment are deposited onto the substrate to form a film.

Here, conventionally, indium oxide-based materials such as ITO are widely used for producing transparent conductive films described above. However, indium metal is rare in the earth and is toxic, which raise concerns over adverse effects on the environment and the human body. For these reasons, there is a demand for indium-free materials.

As the indium-free materials, zinc oxide (ZnO)-based materials containing aluminum or gallium as a dopant and tin oxide (SnO₂)-based materials containing antimony or fluorine as a dopant are known as mentioned above. Transparent conductive films of the above zinc oxide (ZnO)-based materials are industrially produced by the sputtering method. However, these transparent conductive films are disadvantageous because of their poor chemical resistance (alkaline resistance and acid resistance) and the like. On the other hand, transparent conductive films of tin oxide (SnO₂)-based materials are excellent in chemical resistance, but it is difficult to produce a tin oxide-based sintered body target having a high density and a high durability. Hence, the transparent conductive films described above are disadvantageous in that these transparent conductive films are difficult to produce by the sputtering method.

In light of the above, a sintered body containing a zinc oxide and a tin oxide as main components is proposed as a material for improving these disadvantages. For example, Patent Document 1 describes a sintered body which is composed of a SnO₂ phase and a Zn₂SnO₄ phase and which has an average crystal particle diameter of the Zn₂SnO₄ phase within a range of 1 to 10 lam.

In addition, Patent Document 2 describes a sintered body which has an average crystal particle diameter of 4.5 μm or less and in which a degree of orientation represented by I₍₂₂₂₎/[I₍₂₂₂₎+I₍₄₀₀₎] is 0.52 or more, which is greater than the standard (0.44). Here, I₍₂₂₂₎ and I₍₄₀₀₎ represent integrated intensities of a (222) plane and a (400) plane in the Zn₂SnO₄ phase measured by X-ray diffraction using the CuKα radiation. Moreover, Patent Document 2 also describes a method for producing a sintered body having the above characteristics, in which the sintered body production step includes: the step of sintering the compact inside a sintering furnace in an atmosphere containing oxygen under a condition of 800° C. to 1400° C.; and the step of cooling the inside of the sintering furnace in an inert atmosphere such as Ar gas after completion of keeping of the highest sintering temperature.

In the above method, however, it is difficult to obtain a sufficient density and electrical conductivity in a Sn—Zn—O-based oxide sintered body containing Zn and Sn as main components, though a sintered body strength resistant to a mechanical strength can be obtained. As a result, the characteristics are unsatisfactory and do not meet the requirements for sputtering film formation in a mass production case. In short, in the atmospheric pressure sintering method, there remains a problem in achieving a sintered body having a high density and electrical conductivity.

### CONVENTIONAL ART DOCUMENTS

### Patent Documents

Patent Document 1: Japanese Patent Application Publication No. 2010-037161 (see claim 13 and claim 14)
Patent Document 2: Japanese Patent Application Publication No. 2013-036073 (see claim 1 and claim 3)

### DISCLOSURE OF THE INVENTION

### Problems to be Solved by the Invention

The present invention has been made in view of the above-described demand, and an object thereof is to provide a Sn—Zn—O-based oxide sintered body which has Zn and Sn as main components and which has a high density and low resistance in addition to a mechanical strength, and a method for producing the same.

A Sn—Zn—O-based oxide sintered body containing Zn and Sn as main components is a material having difficulty in achieving both the characteristics of high density and low resistance. Even when the composition is changed, it is difficult to produce an oxide sintered body which is high in density and excellent in electrical conductivity. Regarding the sintered body density, the density varies to some extent depending on the blend ratio. Regarding the electrical conductivity, on the other hand, the specific electrical resistance value is 1×10⁶ Ω·cm or more, which is very high and is a low electrical conductivity.

In the production of a Sn—Zn—O-based oxide sintered body containing Zn and Sn as main components, a compound called Zn SnO₄ begins to produce at around 1100° C., and Zn begins to significantly vaporize at around 1450° C. Grain boundary diffusion and interparticle bonding weaken because sintering at a high temperature for the purpose of increasing the density of the Sn—Zn—O-based oxide sintered body accelerates the vaporization of Zn. As a result, it is impossible to obtain a high-density oxide sintered body.

On the other hand, regarding the electrical conductivity, it is impossible to improve the electrical conductivity to a great extent even when the compound phase or the amount of ZnO and SnO₂ is adjusted by adjusting the blend ratio because Zn SnO₄, ZnO, and SnO₂ are substances having a poor electrical conductivity. As a consequence, in the case of a Sn—Zn—O-based oxide sintered body containing Zn and Sn as main components, it is impossible to obtain a high density and a high electrical conductivity of a sintered body, which are characteristics required for sputtering film formation in a mass production case.

To sum up, an object of the present invention is to provide a Sn—Zn—O-based oxide sintered body which is dense and excellent in electrical conductivity and which has Zn and Sn as main components as described above by giving means of improving electrical conductivity to an oxide sintered body which has a strong interparticle bonding achieved by suppressing the vaporization of Zn and accelerating grain boundary diffusion.

### Means for Solving the Problems

In this respect, in order to solve the above problems, the present inventors have searched for production conditions which achieve compatibility of both the characteristics, the density and the electrical conductivity of the sintered body, and have made studies on a method for producing a Sn—Zn—O-based oxide sintered body which has Zn and Sn as main components and which is dense and excellent in high electrical conductivity within a temperature region from 1100° C. at which the compound called Zn SnO₄ begins to produce to 1450° C. at which Zn begins to significantly vaporize.

As a consequence, the present inventors successfully obtained an oxide sintered body having a relative density of 90% by adding as a dopant at least one (specifically, a first additional element M) selected from Si, Ti, Ge, In, Bi, Ce, Al, and Ga under a condition that Sn was contained with an atomic ratio of Sn/(Sn+Zn) being 0.1 or more and 0.9 or less. However, although the density improved, the electrical conductivity was not improved. For the purpose of improving the electrical conductivity, the present inventors further added one of the additional elements Nb, Ta, W, and Mo (specifically, a second additional element X). As a result, it became possible to produce an oxide sintered body excellent in electrical conductivity while maintaining a high density. Note that if Sn is contained with an atomic ratio of Sn/(Sn+Zn) being 0.1 to 0.33, the main components are the ZnO phase of a wurtzite-type crystal structure and the Zn₂SnO₄ phase of a spinel type crystal structure, and that if Sn is contained with an atomic ratio of Sn/(Sn+Zn) being more than 0.33 and 0.9 or less, the main components are the Zn₂SnO₄ phase of a spinel type crystal structure and the SnO₂ phase of a rutile-type crystal structure. In addition, if an appropriate amount of first additional element M and second additional element X is added, these first additional element M and second additional element X are substituted for Zn in the ZnO phase, Zn or Sn in the Zn₂SnO₄ phase, and Sn in the SnO₂ phase, followed by solid dissolution. For this reason, no compound phase is formed except for the ZnO phase of a wurtzite-type crystal structure, the Zn SnO₄ phase of a spinel type crystal structure, and the SnO₂ phase of a rutile-type crystal structure. The present invention has been completed based on these technical findings.

Specifically, a first aspect according to the present invention is a Sn—Zn—O-based oxide sintered body comprising Zn and Sn as main components, wherein

Sn is contained with an atomic ratio of Sn/(Sn+Zn) being 0.1 or more and 0.9 or less,

a first additional element M is contained with an atomic ratio of M/(Sn+Zn+M+X) being 0.0001 or more and 0.04 or less relative to a total amount of all the metal elements, and

a second additional element X is contained with an atomic ratio of X/(Sn+Zn+M+X) being 0.0001 or more and 0.1 or less relative to the total amount of all the metal elements, where
the first additional element M is at least one selected from Si, Ti, Ge, In, Bi, Ce, Al, and Ga, and
the second additional element X is at least one selected from Nb, Ta, W, and Mo, and

a relative density of the sintered body is 90% or more and a specific electrical resistance of the sintered body is 1 Ω·cm or less.

In addition, a second aspect according to the present invention is the Sn—Zn—O-based oxide sintered body described in the first aspect, wherein

an X-ray diffraction peak position of the (101) plane of a ZnO phase is 36.25 degrees to 36.31 degrees, and an X-ray diffraction peak position of the (311) plane of a Zn₂SnO₄ phase is 34.32 degrees to 34.42 degrees, as measured by X-ray diffraction using the CuKα radiation.

A third aspect is the Sn—Zn—O-based oxide sintered body described in the first aspect, wherein

an X-ray diffraction peak position of the (311) plane of a Zn₂SnO₄ phase is 34.32 degrees to 34.42 degrees, and an X-ray diffraction peak position of the (101) plane of a SnO₂ phase is 33.86 degrees to 33.91 degrees, as measured by X-ray diffraction using the CuKα radiation.

Next, a fourth aspect according to the present invention is a method for producing the Sn—Zn—O-based oxide sintered body described in any one of the first aspect to the third aspect, including:

a granulated powder production step of producing a granulated powder by drying a slurry obtained by mixing a ZnO powder, a SnO₂ powder, an oxide powder containing at least one first additional element M selected from Si, Ti, Ge, In, Bi, Ce, Al, and Ga, and an oxide powder containing at least one second additional element X selected from Nb, Ta, W, and Mo, with pure water, an organic binder, and a dispersing agent, followed by granulation;

a compact production step of obtaining a compact by pressing the granulated powder; and

a sintered body production step of obtaining a sintered body by sintering the compact inside a sintering furnace in an atmosphere with an oxygen concentration of 70% by volume or more under conditions of 1200° C. or more and 1450° C. or less and 10 hours or more and 30 hours or less.

### Effects of the Invention

When a Sn—Zn—O-based oxide sintered body according to the present invention satisfies a condition that Sn is contained with an atomic ratio of Sn/(Sn+Zn) being 0.1 or more and 0.9 or less, it is possible to obtain at any blend ratio a high density and low resistance Sn—Zn—O-based oxide sintered body which is excellent in mass productivity by an atmospheric pressure sintering method.

### MODES FOR PRACTICING THE INVENTION

Hereinafter, embodiments of the present invention will be described in detail.

It is possible to produce a Sn—Zn—O-based oxide sintered body according to the present invention having a relative density of 90% or more and a specific electrical resistance of 1 Ω·cm or less by: first preparing a raw material powder which contains Sn with an atomic ratio of Sn/(Sn+Zn) being 0.1 or more and 0.9 or less, which contains at least one first additional element M selected from Si, Ti, Ge, In, Bi, Ce, Al, and Ga with an atomic ratio of M/(Sn+Zn+M+X) being 0.0001 or more and 0.04 or less relative to the total amount of all metal elements, and which contains at least one second additional element X selected from Nb, Ta, W, and Mo with an atomic ratio of X/(Sn+Zn+M+X) being 0.0001 or more and 0.1 or less relative to the total amount of all metal elements; producing a compact by pressing a granulated powder obtained by granulating the raw material powder; and sintering the compact inside the sintering furnace in an atmosphere with an oxygen concentration of 70% by volume or more under the conditions of 1200° C. or more and 1450° C. or less and 10 hours or more and 30 hours or less.

In the following, a method for producing a Sn—Zn-0-based oxide sintered body according to the present invention will be described.

### [Additional Elements]

The first additional element M and the second additional element X are required under the condition that Sn is contained with an atomic ratio of Sn/(Sn+Zn) being 0.1 or more and 0.9 or less because, if only the first additional element M is contained, the density improves but a low resistance characteristic cannot be obtained. On the other hand, if only the second additional element X is contained, a low resistance is achieved but a high density cannot be obtained.

Thus, by adding the first additional element M and the second additional element X, it is possible to obtain a high density and low resistance Sn—Zn—O-based oxide sintered body.

### (First Additional Element M)

In the densification of an oxide sintered body, it is possible to obtain an effect of achieving a high density by adding at least one first additional element M selected from Si, Ti, Ge, In, Bi, Ce, Al, and Ga. The first additional element M described above is considered to contribute to densification by promoting grain boundary diffusion and helping neck growth among particles to strengthen the interparticle bonding. Here, the first additional element is represented by M, and the first additional element M has an atomic ratio of M/(Sn+Zn+M+X) being 0.0001 or more and 0.04 or less relative to the total amount of all metal elements because if the above atomic ratio of M/(Sn+Zn+M+X) is less than 0.0001, an effect of achieving a high density is not exhibited (see Comparative Example 9). On the other hand, if the above atomic ratio of M/(Sn+Zn+M+X) exceeds 0.04, the electrical conductivity of the oxide sintered body does not increase even when a second additional element X to be described later is added (see Comparative Example 10). Moreover, it is impossible to obtain a desired film characteristic in the film formation due to the generation of another compound such as a compound of SiO₂, TiO₂, Al₂O₃, ZnAl₂O₄, ZnSiO₄, Zn₂Ge₃O₂, ZnTa₂O₆, or Ti_{0.5}Sn_{0.5}O₂.

As described above, if only the first additional element M is added, the density of the oxide sintered body improves but the electrical conductivity is not improved.

### (Second Additional Element)

Regarding the Sn—Zn—O-based oxide sintered body added with the above first additional element M under the condition that Sn is contained with an atomic ratio of Sn/(Sn+Zn) being 0.1 or more and 0.9 or less, the density improves as described above but there remains a problem of electrical conductivity.

In light of the above, at least one second additional element X selected from Nb, Ta, W, and Mo is added. By adding the second additional element X, the electrical conductivity is improved while maintaining the high density of the oxide sintered body. Note that the second additional element X is an element having a valence of 5 or more such as Nb, Ta, W, and Mo.

The amount added is required such that the second additional element X has an atomic ratio of X/(Sn+Zn+M+X) being 0.0001 or more and 0.1 or less relative to the total amount of all metal elements. If the above atomic ratio of X/(Sn+Zn+M+X) is less than 0.0001, the electrical conductivity does not increase (see Comparative Example 7). On the other hand, if the above atomic ratio of X/(Sn+Zn+M+X) exceeds 0.1, the electrical conductivity is deteriorated due to the generation of another compound phase such as a compound phase of Nb₂O₅, Ta₂O₅, WO₃, MoO₃, ZnTa₂O₆, ZnWO₄, and ZnMoO₄ (see Comparative Example 8).

### (X-Ray Diffraction Peak)

In the Sn—Zn—O-based oxide sintered body according to the present invention, the main components are a ZnO phase of a wurtzite-type crystal structure and a Zn₂SnO₄ phase of a spinel type crystal structure as described above if the atomic ratio of Sn/(Sn+Zn) is 0.1 to 0.33, and the main components are a Zn₂SnO₄ phase of a spinel type crystal structure and a SnO₂ phase of a rutile-type crystal structure if the atomic ratio of Sn/(Sn+Zn) is more than 0.33 and 0.9 or less. In addition, an appropriate amount of first additional element M and second additional element X is substituted for Zn in the ZnO phase, Zn or Sn in the Zn₂SnO₄ phase, and Sn in the SnO₂ phase, followed by solid dissolution. For this reason, no additional compound phase is formed except for the ZnO phase of a wurtzite-type crystal structure, the Zn₂SnO₄ phase of a spinel type crystal structure, and the SnO₂ phase of a rutile-type crystal structure.

It is possible to acquire knowledge on the crystal structure by carrying out X-ray diffraction analysis on powder obtained by grinding a portion of the above oxide sintered body and then analyzing the obtained diffraction peak. For example, in X-ray diffraction analysis using CuKα radiation, the standard diffraction peak position of the wurtzite-type ZnO (101) plane is 36.253 degrees according to ICDD reference code 00-036-1451. The standard diffraction peak position of the Zn SnO₄ (311) plane of a spinel type crystal structure is 34.291 degrees according to ICDD reference code 00-041-1470, and the standard diffraction peak position of the rutile-type SnO₂ (101) plane is 33.893 degrees according to ICDD reference code 00-041-1445.

Note that the position of diffraction peak is affected by e.g. the type, amount of the additional element, sintering temperature, atmosphere, and retention time and varies because of, for example, expansion, contraction, or distortion of the crystal structure attributed to the substitution position of the additional element in the crystal, oxygen deficiency, internal stress, and the like.

Moreover, in the Sn—Zn—O-based oxide sintered body according to the present invention, the diffraction peak position of the ZnO (101) plane by X-ray diffraction analysis using CuKα radiation is preferably 36.25 degrees to 36.31 degrees including the standard diffraction peak position of 36.253 degrees. In addition, the above diffraction peak position of the Zn SnO₄ (311) plane is preferably 34.32 degrees to 34.42 degrees being angles higher than the standard diffraction peak position of 34.291 degrees, and the diffraction peak position of the SnO₂ (101) plane is preferably 33.86 degrees to 33.91 degrees including the standard diffraction peak position of 33.893 degrees. Out of these ranges, expansion, contraction, or distortion of the ZnO, Zn SnO₄, and SnO₂ crystal proceeds to a large extent, which may cause cracks in the oxide sintered body, a decrease in sintering density, and a decrease in electrical conductivity.

As described above, by adding an appropriate amount of first additional element M and second additional element X, it is possible to obtain a Sn—Zn—O-based oxide sintered body which is high in density and excellent in electrical conductivity.

### [Conditions for Sintering Compact]

### (Atmosphere Inside Furnace)

It is preferable to sinter a compact inside the sintering furnace in an atmosphere with an oxygen concentration of 70% by volume or more. This is because an effect of promoting diffusion of ZnO, SnO₂, and Zn₂SnO₄ compounds, improving a sintering property, and improving electrical conductivity is obtained. In a high-temperature range, an effect of suppressing vaporization of ZnO and Zn₂SnO₄ is also obtained.

On the other hand, if the oxygen concentration inside the sintering furnace is less than 70% by volume, the diffusion of ZnO, SnO₂, and Zn₂SnO₄ compounds reduces. Furthermore, in a high-temperature range, vaporization of the Zn component is promoted and it is impossible to fabricate a dense sintered body (see Comparative Example 3).

### (Sintering Temperature)

The sintering temperature is preferably 1200° C. or more and 1450° C. or less. If the sintering temperature is less than 1200° C. (see Comparative Example 4), the temperature is so low that grain boundary diffusion of sintering in the ZnO, SnO₂, and Zn₂SnO₄ compounds does not proceed. On the other hand, if the temperature exceeds 1450° C. (see Comparative Example 5), grain boundary diffusion is promoted and sintering proceeds. However, even if sintering is performed in a furnace with an oxygen concentration or 70% by volume or more, it is impossible to suppress vaporization of the Zn component. As a result, there remain large pores inside the sintered body.

### (Retention Time)

The retention time is preferably 10 hours or more and 30 hours or less. A retention time less than 10 hours results in insufficient sintering. As a result, the sintered body has a large distortion or warpage, and grain boundary diffusion does not proceed. Hence, sintering does not proceed. Consequently, it is impossible to fabricate a dense sintered body (see Comparative Example 6). On the other hand, if the retention time exceeds 30 hours, it is impossible to obtain a time effect in particular. This results in low work efficiency and high cost.

Since the Sn—Zn—O-based oxide sintered body containing Zn and Sn as main components obtained under the above conditions also has an improved electrical conductivity, film formation by DC sputtering is possible. In addition, the sintered body is applicable to a cylindrical target because no special production method is employed.

### EXAMPLES

Hereinafter, a specific description is provided for the examples of the present invention by using comparative examples. It is a matter of course that the technical scope according to the present invention is not limited to the description of the examples below and that modifications can be made within a scope not departing from the present invention.

### Example 1

A SnO₂ powder having an average particle diameter of 10 μm or less, a ZnO powder having an average particle diameter of 10 μm or less, a Bi₂O₃ powder having an average particle diameter of 20 μm or less as the first additional element M, and a Ta₂O₅ powder having an average particle diameter of 20 μm or less as the second additional element X were prepared.

The SnO₂ powder and the ZnO powder were formulated so that Sn and Zn would have an atomic ratio of Sn/(Sn+Zn) being 0.5, and the Bi₂O₃ powder and the Ta₂O₅ powder were formulated so that the first additional element M would have an atomic ratio of Bi/(Sn+Zn+Bi+Ta) being 0.001 and that the second additional element X would have an atomic ratio of Ta/(Sn+Zn+Bi+Ta) being 0.001.

Then, the formulated raw material powder was mixed with pure water, an organic binder, and a dispersing agent in a mixing tank so that the concentration of the raw material powder would be 60% by mass.

Next, the mixture was ground in a wet manner by using a bead mill apparatus (manufactured by Ashizawa Finetech Ltd., Model: LMZ) into which hard ZrO₂ balls were introduced, until the average particle diameter of the raw material powder became 1 μm or less. Then, the mixture was stirred for mixing for 10 hours or more to obtain a slurry. Note that a laser diffraction particle size distribution analyzer (manufactured by Shimadzu Corporation, SALD-2200) was used for measuring the average particle diameter of the raw material powder.

Next, the obtained slurry was spray dried by using a spray dryer apparatus (manufactured by OHKAWARA KAKOHKI CO., LTD., Model: ODL-20) to obtain a granulated powder.

Next, the obtained granulated powder was filled in a rubber mold and pressed by applying a pressure of 294 MPa (3 ton/cm) thereto with a cold isostatic press to obtain a compact having a diameter of approximately 250 mm. Then, the compact was introduced into an atmospheric-pressure sintering furnace, and air (oxygen concentration of 21% by volume) was introduced into the sintering furnace until the temperature reached 700° C. After it was confirmed that the temperature inside the sintering furnace reached 700° C., oxygen was introduced thereinto so that oxygen concentration would be 80% by volume. Thereafter, the temperature was raised to 1400° C. followed by retention at 1400° C. for 15 hours.

After the retention time was finished, introduction of oxygen was stopped for cooling. Thus, a Sn—Zn—O-based oxide sintered body according to Example 1 was obtained.

Next, a plane grinding machine and a grinding center were used to process the Sn—Zn—O-based oxide sintered body according to Example 1 to have a diameter of 200 mm and a thickness of 5 mm.

When the density of this processed body was measured by the Archimedes method, the relative density was 99.7%. In addition, when the specific electrical resistance was measured by the four-point probe method, the value was 0.003 Ω·cm.

Next, a portion of this processed body was cut and formed into a powder by mortar grinding. Analysis was carried out on this powder by an X-ray diffraction apparatus [X′Pert-PRO (manufactured by PANalytical)] using CuKα radiation. As a result, only the diffraction peaks of the Zn₂SnO₄ phase of a spinel type crystal structure and the SnO₂ phase of a rutile-type crystal structure were measured, and the diffraction peaks of other different compound phases were not measured. The diffraction peak position of the Zn₂SnO₄ (311) plane was 34.39 degrees and the diffraction peak position of the SnO₂ (101) plane was 33.89 degrees, which were normal diffraction peak positions.

Table 1-1, Table 1-2, and Table 1-3 show these results.

### Example 2

A Sn—Zn—O-based oxide sintered body according to Example 2 was obtained in the same way as Example 1 except that the formulation was carried out so that Sn and Zn would have an atomic ratio of Sn/(Sn+Zn) being 0.1. When X-ray diffraction analysis was carried out on the powder in the same way as Example 1, only the diffraction peaks of the wurtzite-type ZnO phase and the Zn₂SnO₄ phase of a spinel type crystal structure were measured, and the diffraction peaks of other different compound phases were not measured. The diffraction peak position of the ZnO (101) plane was 36.28 degrees and the diffraction peak position of the Zn₂SnO₄ (311) plane was 34.34 degrees, which were normal diffraction peak positions. In addition, the relative density was 93.0% and the specific electrical resistance value was 0.57 Ω·cm. Table 1-1, Table 1-2, and Table 1-3 show these results.

### Example 3

A Sn—Zn—O-based oxide sintered body according to Example 3 was obtained in the same way as Example 1 except that the formulation was carried out so that Sn and Zn would have an atomic ratio of Sn/(Sn+Zn) being 0.3. When X-ray diffraction analysis was carried out on the powder in the same way as Example 1, only the diffraction peaks of the wurtzite-type ZnO phase and the Zn₂SnO₄ phase of a spinel type crystal structure were measured, and the diffraction peaks of other different compound phases were not measured. The diffraction peak position of the ZnO (101) plane was 36.26 degrees and the diffraction peak position of the Zn₂SnO₄ (311) plane was 34.41 degrees, which were normal diffraction peak positions. In addition, the relative density was 94.2% and the specific electrical resistance value was 0.042 Ω·cm. Table 1-1, Table 1-2, and Table 1-3 show these results.

### Example 4

A Sn—Zn—O-based oxide sintered body according to Example 4 was obtained in the same way as Example 1 except that the formulation was carried out so that Sn and Zn would have an atomic ratio of Sn/(Sn+Zn) being 0.7. When X-ray diffraction analysis was carried out on the powder in the same way as Example 1, only the diffraction peaks of the Zn₂SnO₄ phase of a spinel type crystal structure and the SnO₂ phase of a rutile-type crystal structure were measured, and the diffraction peaks of other different compound phases were not measured. The diffraction peak position of the Zn₂SnO₄ (311) plane was 34.36 degrees and the diffraction peak position of the SnO₂ (101) plane was 33.87 degrees, which were normal diffraction peak positions. In addition, the relative density was 99.7% and the specific electrical resistance value was 0.006 Ω·cm. Table 1-1, Table 1-2, and Table 1-3 show these results.

### Example 5

A Sn—Zn—O-based oxide sintered body according to Example 5 was obtained in the same way as Example 1 except that the formulation was carried out so that Sn and Zn would have an atomic ratio of Sn/(Sn+Zn) being 0.9. When X-ray diffraction analysis was carried out on the powder in the same way as Example 1, only the diffraction peaks of the Zn₂SnO₄ phase of a spinel type crystal structure and the SnO₂ phase of a rutile-type crystal structure were measured, and the diffraction peaks of other different compound phases were not measured. The diffraction peak position of the Zn₂SnO₄ (311) plane was 34.40 degrees and the diffraction peak position of the SnO₂ (101) plane was 33.90 degrees, which were normal diffraction peak positions. In addition, the relative density was 92.7% and the specific electrical resistance value was 0.89 Ω·cm. Table 1-1, Table 1-2, and Table 1-3 show these results.

### Example 6

A Sn—Zn—O-based oxide sintered body according to Example 6 was obtained in the same way as Example 1 except that the formulation was carried out so that the second additional element X would have an atomic ratio of Ta/(Sn+Zn+Bi+Ta) being 0.0001. When X-ray diffraction analysis was carried out on the powder in the same way as Example 1, only the diffraction peaks of the Zn₂SnO₄ phase of a spinel type crystal structure and the SnO₂ phase of a rutile-type crystal structure were measured, and the diffraction peaks of other different compound phases were not measured. The diffraction peak position of the Zn₂SnO₄ (311) plane was 34.33 degrees and the diffraction peak position of the SnO₂ (101) plane was 33.87 degrees, which were normal diffraction peak positions. In addition, the relative density was 98.5% and the specific electrical resistance value was 0.085 Ω·cm. Table 1-1, Table 1-2, and Table 1-3 show the results.

### Example 7

A Sn—Zn—O-based oxide sintered body according to Example 7 was obtained in the same way as Example 1 except that the oxygen concentration was 100% by volume. When X-ray diffraction analysis was carried out on the powder in the same way as Example 1, only the diffraction peaks of the Zn₂SnO₄ phase of a spinel type crystal structure and the SnO₂ phase of a rutile-type crystal structure were measured, and the diffraction peaks of other different compound phases were not measured. The diffraction peak position of the Zn₂SnO₄ (311) plane was 34.42 degrees and the diffraction peak position of the SnO₂ (101) plane was 33.90 degrees, which were normal diffraction peak positions. In addition, the relative density was 99.6% and the specific electrical resistance value was 0.013 Ω·cm. Table 1-1, Table 1-2, and Table 1-3 show the results.

### Example 8

A Sn—Zn—O-based oxide sintered body according to Example 8 was obtained in the same way as Example 1 except that the formulation was carried out so that the second additional element X would have an atomic ratio of Ta/(Sn+Zn+Bi+Ta) being 0.1, the retention time was 10 hours, and the oxygen concentration was 70% by volume. When X-ray diffraction analysis was carried out on the powder in the same way as Example 1, only the diffraction peaks of the Zn₂SnO₄ phase of a spinel type crystal structure and the SnO₂ phase of a rutile-type crystal structure were measured, and the diffraction peaks of other different compound phases were not measured. The diffraction peak position of the Zn₂SnO₄ (311) plane was 34.37 degrees and the diffraction peak position of the SnO₂ (101) plane was 33.87 degrees, which were normal diffraction peak positions. In addition, the relative density was 94.6% and the specific electrical resistance value was 0.023 Ω·cm. Table 1-1, Table 1-2, and Table 1-3 show the results.

### Example 9

A Sn—Zn—O-based oxide sintered body according to Example 9 was obtained in the same way as Example 1 except that the formulation was carried out so that the first additional element M would have an atomic ratio of Bi/(Sn+Zn+Bi+Ta) being 0.0001 and the sintering temperature was 1450° C. When X-ray diffraction analysis was carried out on the powder in the same way as Example 1, only the diffraction peaks of the Zn₂SnO₄ phase of a spinel type crystal structure and the SnO₂ phase of a rutile-type crystal structure were measured, and the diffraction peaks of other different compound phases were not measured. The diffraction peak position of the Zn₂SnO₄ (311) plane was 34.35 degrees and the diffraction peak position of the SnO₂ (101) plane was 33.91 degrees, which were normal diffraction peak positions. In addition, the relative density was 97.3% and the specific electrical resistance value was 0.08 Ω·cm. Table 1-1, Table 1-2, and Table 1-3 show the results.

### Example 10

A Sn—Zn—O-based oxide sintered body according to Example 10 was obtained in the same way as Example 1 except that the formulation was carried out so that the first additional element M would have an atomic ratio of Bi/(Sn+Zn+Bi+Ta) being 0.04 and the sintering temperature was 1200° C. When X-ray diffraction analysis was carried out on the powder in the same way as Example 1, only the diffraction peaks of the Zn₂SnO₄ phase of a spinel type crystal structure and the SnO₂ phase of a rutile-type crystal structure were measured, and the diffraction peaks of other different compound phases were not measured. The diffraction peak position of the Zn₂SnO₄ (311) plane was 34.36 degrees and the diffraction peak position of the SnO₂ (101) plane was 33.88 degrees, which were normal diffraction peak positions. In addition, the relative density was 96.4% and the specific electrical resistance value was 0.11 Ω·cm. Table 1-1, Table 1-2, and Table 1-3 show the results.

TABLE 1-1

| | First | Second | | | |
|---|---|---|---|---|---|
| | Additional | Additional | Atomic Ratio | | |
| | Element M | Element X | Sn/(Sn + Zn) | M/(Sn + Zn + M + X) | X/(Sn + Zn + M + X) |
| Example 1 | Bi₂O₃ | Ta₂O₅ | 0.5 | 0.001 | 0.001 |
| Example 2 | Bi₂O₃ | Ta₂O₅ | 0.1 | 0.001 | 0.001 |
| Example 3 | Bi₂O₃ | Ta₂O₅ | 0.3 | 0.001 | 0.001 |
| Example 4 | Bi₂O₃ | Ta₂O₅ | 0.7 | 0.001 | 0.001 |
| Example 5 | Bi₂O₃ | Ta₂O₅ | 0.9 | 0.001 | 0.001 |
| Example 6 | Bi₂O₃ | Ta₂O₅ | 0.5 | 0.001 | 0.0001 |
| Example 7 | Bi₂O₃ | Ta₂O₅ | 0.5 | 0.001 | 0.001 |
| Example 8 | Bi₂O₃ | Ta₂O₅ | 0.5 | 0.001 | 0.1 |
| Example 9 | Bi₂O₃ | Ta₂O₅ | 0.5 | 0.0001 | 0.001 |
| Example 10 | Bi₂O₃ | Ta₂O₅ | 0.5 | 0.04 | 0.001 |

TABLE 1-2

| | | | | | Specific |
|---|---|---|---|---|---|
| | Sintering | Reten- | Oxygen | | Electrical |
| | Temper- | tion | Concen- | Relative | Resistance |
| | ature | Time | tration | Density | Value |
| | (° C.) | (Hours) | (% by Volume) | (%) | (Ω · cm) |
| Example 1 | 1400 | 15 | 80 | 99.7 | 0.003 |
| Example 2 | 1400 | 15 | 80 | 93.0 | 0.57 |
| Example 3 | 1400 | 15 | 80 | 94.2 | 0.042 |
| Example 4 | 1400 | 15 | 80 | 99.7 | 0.006 |
| Example 5 | 1400 | 15 | 80 | 92.7 | 0.89 |
| Example 6 | 1400 | 15 | 80 | 98.5 | 0.085 |
| Example 7 | 1400 | 15 | 100 | 99.6 | 0.013 |
| Example 8 | 1400 | 10 | 70 | 94.6 | 0.023 |
| Example 9 | 1450 | 15 | 80 | 97.3 | 0.08 |
| Example 10 | 1200 | 15 | 80 | 96.4 | 0.11 |

TABLE 1-3
X-Ray Diffraction Peak Position (Degrees)

| | ZnO (101) | Zn2SnO4 (311) | SnO2 (101) |
|---|---|---|---|
| Example 1 | — | 34.39 | 33.89 |
| Example 2 | 36.28 | 34.34 | — |
| Example 3 | 36.26 | 34.41 | — |
| Example 4 | — | 34.36 | 33.87 |
| Example 5 | — | 34.40 | 33.90 |
| Example 6 | — | 34.33 | 33.87 |
| Example 7 | — | 34.42 | 33.90 |
| Example 8 | — | 34.37 | 33.87 |
| Example 9 | — | 34.35 | 33.91 |
| Example 10 | — | 34.36 | 33.88 |

### Examples 11 to 17

Sn—Zn—O-based oxide sintered bodies according to Examples 11 to 17 were obtained in the same way as Example 1 except that the formulation was carried out such that a SiO₂ powder (Example 11), a TiO₂ powder (Example 12), a GeO₂ powder (Example 13), a In₂O₃ powder (Example 14), a CeO₂ powder (Example 15), an Al₂O₃ powder (Example 16), and a Ga₂O₃ powder (Example 17) were used as the first additional element M, the first additional element M had an atomic ratio of M/(Sn+Zn+M+Ta) being 0.04, the same Ta₂O₅ powder as Example 1 was used as the second additional element X, and the second additional element X had an atomic ratio of Ta/(Sn+Zn+M+Ta) being 0.1.

Additionally, when X-ray diffraction analysis was carried out on each of the Sn—Zn—O-based oxide sintered bodies according to the examples, only the diffraction peaks of the Zn₂SnO₄ phase of a spinel type crystal structure and the SnO₂ phase of a rutile-type crystal structure were measured, and the diffraction peaks of other different compound phases were not measured. In addition, the combinations of diffraction peak positions of the Zn₂SnO₄ (311) plane and the SnO₂ (101) plane for the Sn—Zn—O-based oxide sintered bodies according to the examples were 34.32 degrees and 33.87 degrees (Example 11), 34.36 degrees and 33.90 degrees (Example 12), 34.40 degrees and 33.86 degrees (Example 13), 34.32 degrees and 33.88 degrees (Example 14), 34.34 degrees and 33.91 degrees (Example 15), 34.35 degrees and 33.86 degrees (Example 16), and 34.38 degrees and 33.91 degrees (Example 17), which were normal diffraction peak positions. Table 2-1, Table 2-2, and Table 2-3 show the results.

In addition, the combinations of relative density and specific electrical resistance value for the Sn—Zn—O-based oxide sintered bodies according to the examples were 94.5% and 0.08 Ω·cm (Example 11), 95.1% and 0.21 Ω·cm (Example 12), 97.0% and 0.011 Ω·cm (Example 13), 96.1% and 0.048 Ω·cm (Example 14), 94.8% and 0.013 Ω·cm (Example 15), 94.6% and 0.18 Ω·cm (Example 16), and 95.3% and 0.48 Ω·cm (Example 17). Table 2-1, Table 2-2, and Table 2-3 show the results.

### Examples 18 to 24

Sn—Zn—O-based oxide sintered bodies according to Examples 18 to 24 were obtained in the same way as Example 1 except that the formulation was carried out such that a SiO₂ powder (Example 18), a TiO₂ powder (Example 19), a GeO₂ powder (Example 20), a In₂O₃ powder (Example 21), a CeO₂ powder (Example 22), an Al₂O₃ powder (Example 23), and a Ga₂O₃ powder (Example 24) were used as the first additional element M, the first additional element M had an atomic ratio of M/(Sn+Zn+M+Ta) being 0.0001, the same Ta₂O₅ powder as Example 1 was used as the second additional element X, and the second additional element X had an atomic ratio of Ta/(Sn+Zn+M+Ta) being 0.1.

Additionally, when X-ray diffraction analysis was carried out on each of the Sn—Zn—O-based oxide sintered bodies according to the examples, only the diffraction peaks of the Zn₂SnO₄ phase of a spinel type crystal structure and the SnO₂ phase of a rutile-type crystal structure were measured, and the diffraction peaks of other different compound phases were not measured. In addition, the combinations of diffraction peak positions of the Zn₂SnO₄ (311) plane and the SnO₂ (101) plane for the Sn—Zn—O-based oxide sintered bodies according to the examples were 34.33 degrees and 33.89 degrees (Example 18), 34.32 degrees and 33.90 degrees (Example 19), 34.41 degrees and 33.88 degrees (Example 20), 34.39 degrees and 33.87 degrees (Example 21), 34.42 degrees and 33.89 degrees (Example 22), 34.37 degrees and 33.89 degrees (Example 23), and 34.38 degrees and 33.88 degrees (Example 24), which were normal diffraction peak positions. Table 2-1, Table 2-2, and Table 2-3 show the results.

In addition, the combinations of relative density and specific electrical resistance value for the Sn—Zn—O-based oxide sintered bodies according to the examples were 93.3% and 0.011 Ω·cm (Example 18), 96.1% and 0.07 Ω·cm (Example 19), 95.0% and 0.021 Ω·cm (Example 20), 94.6% and 0.053 Ω·cm (Example 21), 96.1% and 0.08 Ω·cm (Example 22), 95.2% and 0.14 Ω·cm (Example 23), and 96.0% and 0.066 Ω·cm (Example 24). Table 2-1, Table 2-2, and Table 2-3 show the results.

### Examples 25 to 31

Sn—Zn—O-based oxide sintered bodies according to Examples 25 to 31 were obtained in the same way as Example 1 except that the formulation was carried out such that a SiO₂ powder (Example 25), a TiO₂ powder (Example 26), a GeO₂ powder (Example 27), a In₂O₃ powder (Example 28), a CeO₂ powder (Example 29), an Al₂O₃ powder (Example 30), and a Ga₂O₃ powder (Example 31) were used as the first additional element M, the first additional element M had an atomic ratio of M/(Sn+Zn+M+Ta) being 0.04, the same Ta₂O₅ powder as Example 1 was used as the second additional element X, and the second additional element X had an atomic ratio of Ta/(Sn+Zn+M+Ta) being 0.0001.

Additionally, when X-ray diffraction analysis was carried out on each of the Sn—Zn—O-based oxide sintered bodies according to the examples, only the diffraction peaks of the Zn₂SnO₄ phase of a spinel type crystal structure and the SnO₂ phase of a rutile-type crystal structure were measured, and the diffraction peaks of other different compound phases were not measured. In addition, the combinations of diffraction peak positions of the Zn₂SnO₄ (311) plane and the SnO₂ (101) plane for the Sn—Zn—O-based oxide sintered bodies according to the examples were 34.32 degrees and 33.91 degrees (Example 25), 34.37 degrees and 33.86 degrees (Example 26), 34.42 degrees and 33.91 degrees (Example 27), 34.34 degrees and 33.88 degrees (Example 28), 34.40 degrees and 33.91 degrees (Example 29), 34.34 degrees and 33.86 degrees (Example 30), and 34.38 degrees and 33.90 degrees (Example 31), which were normal diffraction peak positions. Table 2-1, Table 2-2, and Table 2-3 show the results.

In addition, the combinations of relative density and specific electrical resistance value for the Sn—Zn—O-based oxide sintered bodies according to the examples were 97.6% and 0.092 Ω·cm (Example 25), 97.9% and 0.0082 Ω·cm (Example 26), 97.9% and 0.0033 Ω·cm (Example 27), 97.5% and 0.0032 Ω·cm (Example 28), 98.7% and 0.009 Ω·cm (Example 29), 97.0% and 0.0054 Ω·cm (Example 30), and 99.1% and 0.009 Ω·cm (Example 31). Table 2-1, Table 2-2, and Table 2-3 show the results.

### Examples 32 to 38

Sn—Zn—O-based oxide sintered bodies according to Examples 32 to 38 were obtained in the same way as Example 1 except that the formulation was carried out such that a SiO₂ powder (Example 32), a TiO₂ powder (Example 33), a GeO₂ powder (Example 34), a In₂O₃ powder (Example 35), a CeO₂ powder (Example 36), an Al₂O₃ powder (Example 37), and a Ga₂O₃ powder (Example 38) were used as the first additional element M, the first additional element M had an atomic ratio of M/(Sn+Zn+M+Ta) being 0.0001, the same Ta₂O₅ powder as Example 1 was used as the second additional element X, and the second additional element X had an atomic ratio of Ta/(Sn+Zn+M+Ta) being 0.0001.

Additionally, when X-ray diffraction analysis was carried out on each of the Sn—Zn—O-based oxide sintered bodies according to the examples, only the diffraction peaks of the Zn₂SnO₄ phase of a spinel type crystal structure and the SnO₂ phase of a rutile-type crystal structure were measured, and the diffraction peaks of other different compound phases were not measured. In addition, the combinations of diffraction peak positions of the Zn SnO₄ (311) plane and the SnO₂ (101) plane for the Sn—Zn—O-based oxide sintered bodies according to the examples were 34.36 degrees and 33.91 degrees (Example 32), 34.35 degrees and 33.87 degrees (Example 33), 34.42 degrees and 33.87 degrees (Example 34), 34.42 degrees and 33.86 degrees (Example 35), 34.41 degrees and 33.90 degrees (Example 36), 34.32 degrees and 33.87 degrees (Example 37), and 34.40 degrees and 33.88 degrees (Example 38), which were normal diffraction peak positions. Table 2-1, Table 2-2, and Table 2-3 show the results.

In addition, the combinations of relative density and specific electrical resistance value for the Sn—Zn—O-based oxide sintered bodies according to the examples were 98.0% and 0.013 Ω·cm (Example 32), 97.5% and 0.0021 Ω·cm (Example 33), 97.8% and 0.012 Ω·cm (Example 34), 97.9% and 0.027 Ω·cm (Example 35), 98.0% and 0.0053 Ω·cm (Example 36), 98.5% and 0.0066 Ω·cm (Example 37), and 98.8% and 0.0084 Ω·cm (Example 38). Table 2-1, Table 2-2, and Table 2-3 show the results.

TABLE 2-1

| | First | Second | | | |
|---|---|---|---|---|---|
| | Additional | Additional | Atomic Ratio | | |
| | Element M | Element X | Sn/(Sn + Zn) | M/(Sn + Zn + M + X) | X/(Sn + Zn + M + X) |
| Example 11 | SiO₂ | Ta₂O₅ | 0.5 | 0.04 | 0.1 |
| Example 12 | TiO₂ | Ta₂O₅ | 0.5 | 0.04 | 0.1 |
| Example 13 | GeO₂ | Ta₂O₅ | 0.5 | 0.04 | 0.1 |
| Example 14 | In₂O₃ | Ta₂O₅ | 0.5 | 0.04 | 0.1 |
| Example 15 | CeO₂ | Ta₂O₅ | 0.5 | 0.04 | 0.1 |
| Example 16 | Al₂O₃ | Ta₂O₅ | 0.5 | 0.04 | 0.1 |
| Example 17 | Ga₂O₃ | Ta₂O₅ | 0.5 | 0.04 | 0.1 |
| Example 18 | SiO₂ | Ta₂O₅ | 0.5 | 0.0001 | 0.1 |
| Example 19 | TiO₂ | Ta₂O₅ | 0.5 | 0.0001 | 0.1 |
| Example 20 | GeO₂ | Ta₂O₅ | 0.5 | 0.0001 | 0.1 |
| Example 21 | In₂O₃ | Ta₂O₅ | 0.5 | 0.0001 | 0.1 |
| Example 22 | CeO₂ | Ta₂O₅ | 0.5 | 0.0001 | 0.1 |
| Example 23 | Al₂O₃ | Ta₂O₅ | 0.5 | 0.0001 | 0.1 |
| Example 24 | Ga₂O₃ | Ta₂O₅ | 0.5 | 0.0001 | 0.1 |
| Example 25 | SiO₂ | Ta₂O₅ | 0.5 | 0.04 | 0.0001 |
| Example 26 | TiO₂ | Ta₂O₅ | 0.5 | 0.04 | 0.0001 |
| Example 27 | GeO₂ | Ta₂O₅ | 0.5 | 0.04 | 0.0001 |
| Example 28 | In₂O₃ | Ta₂O₅ | 0.5 | 0.04 | 0.0001 |
| Example 29 | CeO₂ | Ta₂O₅ | 0.5 | 0.04 | 0.0001 |
| Example 30 | Al₂O₃ | Ta₂O₅ | 0.5 | 0.04 | 0.0001 |
| Example 31 | Ga₂O₃ | Ta₂O₅ | 0.5 | 0.04 | 0.0001 |
| Example 32 | SiO₂ | Ta₂O₅ | 0.5 | 0.0001 | 0.0001 |
| Example 33 | TiO₂ | Ta₂O₅ | 0.5 | 0.0001 | 0.0001 |
| Example 34 | GeO₂ | Ta₂O₅ | 0.5 | 0.0001 | 0.0001 |
| Example 35 | In₂O₃ | Ta₂O₅ | 0.5 | 0.0001 | 0.0001 |
| Example 36 | CeO₂ | Ta₂O₅ | 0.5 | 0.0001 | 0.0001 |
| Example 37 | Al₂O₃ | Ta₂O₅ | 0.5 | 0.0001 | 0.0001 |
| Example 38 | Ga₂O₃ | Ta₂O₅ | 0.5 | 0.0001 | 0.0001 |

TABLE 2-2

| | | | | | Specific |
|---|---|---|---|---|---|
| | Sintering | Reten- | Oxygen | | Electrical |
| | Temper- | tion | Concen- | Relative | Resistance |
| | ature | Time | tration | Density | Value |
| | (° C.) | (Hours) | (% by Volume) | (%) | (Ω · cm) |
| Example 11 | 1400 | 15 | 80 | 94.5 | 0.08 |
| Example 12 | 1400 | 15 | 80 | 95.1 | 0.21 |
| Example 13 | 1400 | 15 | 80 | 97.0 | 0.011 |
| Example 14 | 1400 | 15 | 80 | 96.1 | 0.048 |
| Example 15 | 1400 | 15 | 80 | 94.8 | 0.013 |
| Example 16 | 1400 | 15 | 80 | 94.6 | 0.18 |
| Example 17 | 1400 | 15 | 80 | 95.3 | 0.48 |
| Example 18 | 1400 | 15 | 80 | 93.3 | 0.011 |
| Example 19 | 1400 | 15 | 80 | 96.1 | 0.07 |
| Example 20 | 1400 | 15 | 80 | 95.0 | 0.021 |
| Example 21 | 1400 | 15 | 80 | 94.6 | 0.053 |
| Example 22 | 1400 | 15 | 80 | 96.1 | 0.08 |
| Example 23 | 1400 | 15 | 80 | 95.2 | 0.14 |
| Example 24 | 1400 | 15 | 80 | 96.0 | 0.066 |
| Example 25 | 1400 | 15 | 80 | 97.6 | 0.092 |
| Example 26 | 1400 | 15 | 80 | 97.9 | 0.0082 |
| Example 27 | 1400 | 15 | 80 | 97.9 | 0.0033 |
| Example 28 | 1400 | 15 | 80 | 97.5 | 0.0032 |
| Example 29 | 1400 | 15 | 80 | 98.7 | 0.009 |
| Example 30 | 1400 | 15 | 80 | 97.0 | 0.0054 |
| Example 31 | 1400 | 15 | 80 | 99.1 | 0.009 |
| Example 32 | 1400 | 15 | 80 | 98.0 | 0.013 |
| Example 33 | 1400 | 15 | 80 | 97.5 | 0.0021 |
| Example 34 | 1400 | 15 | 80 | 97.8 | 0.012 |
| Example 35 | 1400 | 15 | 80 | 97.9 | 0.027 |
| Example 36 | 1400 | 15 | 80 | 98.0 | 0.0053 |
| Example 37 | 1400 | 15 | 80 | 98.5 | 0.0066 |
| Example 38 | 1400 | 15 | 80 | 98.8 | 0.0084 |

TABLE 2-3
X-Ray Diffraction Peak Position (Degrees)

| | ZnO (101) | Zn2SnO4 (311) | SnO2 (101) |
|---|---|---|---|
| Example 11 | — | 34.32 | 33.87 |
| Example 12 | — | 34.36 | 33.90 |
| Example 13 | — | 34.40 | 33.86 |
| Example 14 | — | 34.32 | 33.88 |
| Example 15 | — | 34.34 | 33.91 |
| Example 16 | — | 34.35 | 33.86 |
| Example 17 | — | 34.38 | 33.91 |
| Example 18 | — | 34.33 | 33.89 |
| Example 19 | — | 34.32 | 33.90 |
| Example 20 | — | 34.41 | 33.88 |
| Example 21 | — | 34.39 | 33.87 |
| Example 22 | — | 34.42 | 33.89 |
| Example 23 | — | 34.37 | 33.89 |
| Example 24 | — | 34.38 | 33.88 |
| Example 25 | — | 34.32 | 33.91 |
| Example 26 | — | 34.37 | 33.86 |
| Example 27 | — | 34.42 | 33.91 |
| Example 28 | — | 34.34 | 33.88 |
| Example 29 | — | 34.40 | 33.91 |
| Example 30 | — | 34.34 | 33.86 |
| Example 31 | — | 34.38 | 33.90 |
| Example 32 | — | 34.36 | 33.91 |
| Example 33 | — | 34.35 | 33.87 |
| Example 34 | — | 34.42 | 33.87 |
| Example 35 | — | 34.42 | 33.86 |
| Example 36 | — | 34.41 | 33.90 |
| Example 37 | — | 34.32 | 33.87 |
| Example 38 | — | 34.40 | 33.88 |

### Examples 39 to 41

Sn—Zn—O-based oxide sintered bodies according to Examples 39 to 41 were obtained in the same way as Example 1 except that the formulation was carried out such that the same Bi₂O₃ powder as Example 1 was used as the first additional element M, the first additional element M had an atomic ratio of Bi/(Sn+Zn+Bi+X) being 0.04, a Nb₂O₅ powder (Example 39), a WO₃ powder (Example 40), and a MoO₃ powder (Example 41) were used as the second additional element X, and the second additional element X had an atomic ratio of X/(Sn+Zn+Bi+X) being 0.1.

Additionally, when X-ray diffraction analysis was carried out on each of the Sn—Zn—O-based oxide sintered bodies according to the examples, only the diffraction peaks of the Zn₂SnO₄ phase of a spinel type crystal structure and the SnO₂ phase of a rutile-type crystal structure were measured, and the diffraction peaks of other different compound phases were not measured. In addition, the combinations of diffraction peak positions of the Zn₂SnO₄ (311) plane and the SnO₂ (101) plane for the Sn—Zn—O-based oxide sintered bodies according to the examples were 34.40 degrees and 33.89 degrees (Example 39), 34.35 degrees and 33.90 degrees (Example 40), and 34.39 degrees and 33.86 degrees (Example 41), which were normal diffraction peak positions. Table 3-1, Table 3-2, and Table 3-3 show the results.

In addition, the combinations of relative density and specific electrical resistance value for the Sn—Zn—O-based oxide sintered bodies according to the examples were 97.7% and 0.029 Ω·cm (Example 39), 95.9% and 0.069 Ω·cm (Example 40), and 96.9% and 0.19 Ω·cm (Example 41). Table 3-1, Table 3-2, and Table 3-3 show the results.

### Examples 42 to 44

Sn—Zn—O-based oxide sintered bodies according to Examples 42 to 44 were obtained in the same way as Example 1 except that the formulation was carried out such that the same Bi₂O₃ powder as Example 1 was used as the first additional element M, the first additional element M had an atomic ratio of Bi/(Sn+Zn+Bi+X) being 0.0001, a Nb₂O₅ powder (Example 42), a WO₃ powder (Example 43), and a MoO₃ powder (Example 44) were used as the second additional element X, and the second additional element X had an atomic ratio of X/(Sn+Zn+Bi+X) being 0.1.

Additionally, when X-ray diffraction analysis was carried out on each of the Sn—Zn—O-based oxide sintered bodies according to the examples, only the diffraction peaks of the Zn₂SnO₄ phase of a spinel type crystal structure and the SnO₂ phase of a rutile-type crystal structure were measured, and the diffraction peaks of other different compound phases were not measured. In addition, the combinations of diffraction peak positions of the Zn₂SnO₄ (311) plane and the SnO₂ (101) plane for the Sn—Zn—O-based oxide sintered bodies according to the examples were 34.32 degrees and 33.89 degrees (Example 42), 34.34 degrees and 33.87 degrees (Example 43), and 34.39 degrees and 33.90 degrees (Example 44), which were normal diffraction peak positions. Table 3-1, Table 3-2, and Table 3-3 show the results.

In addition, the combinations of relative density and specific electrical resistance value for the Sn—Zn—O-based oxide sintered bodies according to the examples were 94.8% and 0.021 Ω·cm (Example 42), 96.6% and 0.0096 Ω·cm (Example 43), and 95.6% and 0.0092 Ω·cm (Example 44). Table 3-1, Table 3-2, and Table 3-3 show the results.

### Examples 45 to 47

Sn—Zn—O-based oxide sintered bodies according to Examples 45 to 47 were obtained in the same way as Example 1 except that the formulation was carried out such that the same Bi₂O₃ powder as Example 1 was used as the first additional element M, the first additional element M had an atomic ratio of Bi/(Sn+Zn+Bi+X) being 0.04, a Nb₂O₅ powder (Example 45), a WO₃ powder (Example 46), and a MoO₃ powder (Example 47) were used as the second additional element X, and the second additional element X had an atomic ratio of X/(Sn+Zn+Bi+X) being 0.0001.

Additionally, when X-ray diffraction analysis was carried out on each of the Sn—Zn—O-based oxide sintered bodies according to the examples, only the diffraction peaks of the Zn₂SnO₄ phase of a spinel type crystal structure and the SnO₂ phase of a rutile-type crystal structure were measured, and the diffraction peaks of other different compound phases were not measured. In addition, the combinations of diffraction peak positions of the Zn₂SnO₄ (311) plane and the SnO₂ (101) plane for the Sn—Zn—O-based oxide sintered bodies according to the examples were 34.36 degrees and 33.86 degrees (Example 45), 34.42 degrees and 33.88 degrees (Example 46), and 34.34 degrees and 33.90 degrees (Example 47), which were normal diffraction peak positions. Table 3-1, Table 3-2, and Table 3-3 show the results.

In addition, the combinations of relative density and specific electrical resistance value for the Sn—Zn—O-based oxide sintered bodies according to the examples were 98.1% and 0.022 Ω·cm (Example 45), 97.6% and 0.0066 Ω·cm (Example 46), and 97.7% and 0.0077 Ω·cm (Example 47). Table 3-1, Table 3-2, and Table 3-3 show the results.

### Examples 48 to 50

Sn—Zn—O-based oxide sintered bodies according to Examples 48 to 50 were obtained in the same way as Example 1 except that the formulation was carried out such that the same Bi₂O₃ powder as Example 1 was used as the first additional element M, the first additional element M had an atomic ratio of Bi/(Sn+Zn+Bi+X) being 0.0001, a Nb₂O₅ powder (Example 48), a WO₃ powder (Example 49), and a MoO₃ powder (Example 50) were used as the second additional element X, and the second additional element X had an atomic ratio of X/(Sn+Zn+Bi+X) being 0.0001.

Additionally, when X-ray diffraction analysis was carried out on each of the Sn—Zn—O-based oxide sintered bodies according to the examples, only the diffraction peaks of the Zn₂SnO₄ phase of a spinel type crystal structure and the SnO₂ phase of a rutile-type crystal structure were measured, and the diffraction peaks of other different compound phases were not measured. In addition, the combinations of diffraction peak positions of the Zn₂SnO₄ (311) plane and the SnO₂ (101) plane for the Sn—Zn—O-based oxide sintered bodies according to the examples were 34.35 degrees and 33.88 degrees (Example 48), 34.41 degrees and 33.87 degrees (Example 49), and 34.33 degrees and 33.88 degrees (Example 50), which were normal diffraction peak positions. Table 3-1, Table 3-2, and Table 3-3 show the results.

In addition, the combinations of relative density and specific electrical resistance value for the Sn—Zn—O-based oxide sintered bodies according to the examples were 95.5% and 0.0099 Ω·cm (Example 48), 97.3% and 0.0074 Ω·cm (Example 49), and 97.4% and 0.009 Ω·cm (Example 50). Table 3-1, Table 3-2, and Table 3-3 show the results.

TABLE 3-1

| | First | Second | | | |
|---|---|---|---|---|---|
| | Additional | Additional | Atomic Ratio | | |
| | Element M | Element X | Sn/(Sn + Zn) | M/(Sn + Zn + M + X) | X/Sn + Zn + M + X) |
| Example 39 | Bi₂O₃ | Nb₂O₅ | 0.5 | 0.04 | 0.1 |
| Example 40 | Bi₂O₃ | WO₃ | 0.5 | 0.04 | 0.1 |
| Example 41 | Bi₂O₃ | MoO₃ | 0.5 | 0.04 | 0.1 |
| Example 42 | Bi₂O₃ | Nb₂O₅ | 0.5 | 0.0001 | 0.1 |
| Example 43 | Bi₂O₃ | WO₃ | 0.5 | 0.0001 | 0.1 |
| Example 44 | Bi₂O₃ | MoO₃ | 0.5 | 0.0001 | 0.1 |
| Example 45 | Bi₂O₃ | Nb₂O₅ | 0.5 | 0.04 | 0.0001 |
| Example 46 | Bi₂O₃ | WO₃ | 0.5 | 0.04 | 0.0001 |
| Example 47 | Bi₂O₃ | MoO₃ | 0.5 | 0.04 | 0.0001 |
| Example 48 | Bi₂O₃ | Nb₂O₅ | 0.5 | 0.0001 | 0.0001 |
| Example 49 | Bi₂O₃ | WO₃ | 0.5 | 0.0001 | 0.0001 |
| Example 50 | Bi₂O₃ | MoO₃ | 0.5 | 0.0001 | 0.0001 |

TABLE 3-2

| | | | | | Specific |
|---|---|---|---|---|---|
| | Sintering | Reten- | Oxygen | | Electrical |
| | Temper- | tion | Concen- | Relative | Resistance |
| | ature | Time | tration | Density | Value |
| | (° C.) | (Hours) | (% by Volume) | (%) | (Ω · cm) |
| Example 39 | 1400 | 15 | 80 | 97.7 | 0.029 |
| Example 40 | 1400 | 15 | 80 | 95.9 | 0.069 |
| Example 41 | 1400 | 15 | 80 | 96.9 | 0.19 |
| Example 42 | 1400 | 15 | 80 | 94.8 | 0.021 |
| Example 43 | 1400 | 15 | 80 | 96.6 | 0.0096 |
| Example 44 | 1400 | 15 | 80 | 95.6 | 0.0092 |
| Example 45 | 1400 | 15 | 80 | 98.1 | 0.022 |
| Example 46 | 1400 | 15 | 80 | 97.6 | 0.0066 |
| Example 47 | 1400 | 15 | 80 | 97.7 | 0.0077 |
| Example 48 | 1400 | 15 | 80 | 95.5 | 0.0099 |
| Example 49 | 1400 | 15 | 80 | 97.3 | 0.0074 |
| Example 50 | 1400 | 15 | 80 | 97.4 | 0.009 |

TABLE 3-3
X-Ray Diffraction Peak Position (Degrees)

| | ZnO (101) | Zn2SnO4 (311) | SnO2 (101) |
|---|---|---|---|
| Example 39 | — | 34.40 | 33.89 |
| Example 40 | — | 34.35 | 33.90 |
| Example 41 | — | 34.39 | 33.86 |
| Example 42 | — | 34.32 | 33.89 |
| Example 43 | — | 34.34 | 33.87 |
| Example 44 | — | 34.39 | 33.90 |
| Example 45 | — | 34.36 | 33.86 |
| Example 46 | — | 34.42 | 33.88 |
| Example 47 | — | 34.34 | 33.90 |
| Example 48 | — | 34.35 | 33.88 |
| Example 49 | | 34.41 | 33.87 |
| Example 50 | | 34.33 | 33.88 |

### Comparative Example 1

A Sn—Zn—O-based oxide sintered body according to Comparative Example 1 was obtained in the same way as Example 1 except that the formulation was carried out so that Sn and Zn would have an atomic ratio of Sn/(Sn+Zn) being 0.05.

When X-ray diffraction analysis was carried out on the Sn—Zn—O-based oxide sintered body according to Comparative Example 1 in the same way as Example 1, the diffraction peaks of only the wurtzite-type ZnO phase and the Zn₂SnO₄ phase of a spinel type crystal structure were measured, and the diffraction peaks of different compound phases were not measured. However, the diffraction peak position of the ZnO (101) plane was 36.24 degrees and the diffraction peak position of the Zn₂SnO₄ (311) plane was 34.33 degrees, meaning that the diffraction peak position of the ZnO (101) plane deviated from the normal position. In addition, in the measurement of the relative density and the specific electrical resistance value, the relative density was 88.0% and the specific electrical resistance value was 500 Ω·cm, meaning that the characteristics did not satisfy the conditions of a relative density of 90% or more and a specific electrical resistance of 1 Ω·cm or less. Table 4-1, Table 4-2, and Table 4-3 show the results.

### Comparative Example 2

A Sn—Zn—O-based oxide sintered body according to Comparative Example 2 was obtained in the same way as Example 1 except that the formulation was carried out so that Sn and Zn would have an atomic ratio of Sn/(Sn+Zn) being 0.95.

When X-ray diffraction analysis was carried out on the Sn—Zn—O-based oxide sintered body according to Comparative Example 2 in the same way as Example 1, the diffraction peaks of only the Zn₂SnO₄ phase of a spinel type crystal structure and the SnO₂ phase of a rutile-type crystal structure were measured, and the diffraction peaks of different compound phases were not measured. However, the diffraction peak position of the Zn₂SnO₄ (311) plane was 34.33 degrees and the diffraction peak position of the SnO₂ (101) plane was 33.92 degrees, meaning that the diffraction peak position of the SnO₂ (101) plane deviated from the normal position. In addition, in the measurement of the relative density and the specific electrical resistance value, the relative density was 86.0% and the specific electrical resistance value was 700 Ω·cm, meaning that the characteristics did not satisfy the conditions of a relative density of 90% or more and a specific electrical resistance of 1 Ω·cm or less. Table 4-1, Table 4-2, and Table 4-3 show the results.

### Comparative Example 3

A Sn—Zn—O-based oxide sintered body according to Comparative Example 3 was obtained in the same way as Example 1 except that the oxygen concentration inside the furnace was 68% by volume during the sintering at 1400° C.

When X-ray diffraction analysis was carried out on the Sn—Zn—O-based oxide sintered body according to Comparative Example 3, the diffraction peaks of only the Zn₂SnO₄ phase of a spinel type crystal structure and the SnO₂ phase of a rutile-type crystal structure were measured, and the diffraction peaks of different compound phases were not measured. However, the diffraction peak position of the Zn₂SnO₄ (311) plane was 34.39 degrees and the diffraction peak position of the SnO₂ (101) plane was 33.93 degrees, meaning that the diffraction peak position of the SnO₂ (101) plane deviated from the normal position. In addition, in the measurement of the relative density and the specific electrical resistance value, the relative density was 87.3% and the specific electrical resistance value was 53000 Ω·cm, meaning that the characteristics did not satisfy the conditions of a relative density of 90% or more and a specific electrical resistance of 1 Ω·cm or less. Table 4-1, Table 4-2, and Table 4-3 show the results.

### Comparative Example 4

A Sn—Zn—O-based oxide sintered body according to Comparative Example 4 was obtained in the same way as Example 1 except that the sintering temperature was 1170° C.

When X-ray diffraction analysis was carried out on the Sn—Zn—O-based oxide sintered body according to Comparative Example 4, the diffraction peaks of only the Zn₂SnO₄ phase of a spinel type crystal structure and the SnO₂ phase of a rutile-type crystal structure were measured, and the diffraction peaks of different compound phases were not measured. However, the diffraction peak position of the Zn₂SnO₄ (311) plane was 34.29 degrees and the diffraction peak position of the SnO₂ (101) plane was 33.88 degrees, meaning that the diffraction peak position of the Zn₂SnO₄ (311) plane deviated from the normal position. In addition, in the measurement of the relative density and the specific electrical resistance value, the relative density was 82.2% and the specific electrical resistance value was 61000 Ω·cm, meaning that the characteristics did not satisfy the conditions of a relative density of 90% or more and a specific electrical resistance of 1 Ω·cm or less. Table 4-1, Table 4-2, and Table 4-3 show the results.

### Comparative Example 5

A Sn—Zn—O-based oxide sintered body according to Comparative Example 5 was obtained in the same way as Example 1 except that the sintering temperature was 1500° C.

When X-ray diffraction analysis was carried out on the Sn—Zn—O-based oxide sintered body according to Comparative Example 5, the diffraction peaks of only the Zn₂SnO₄ phase of a spinel type crystal structure and the SnO₂ phase of a rutile-type crystal structure were measured, and the diffraction peaks of different compound phases were not measured. However, the diffraction peak position of the Zn₂SnO₄ (311) plane was 34.34 degrees and the diffraction peak position of the SnO₂ (101) plane was 33.95 degrees, meaning that the diffraction peak position of the SnO₂ (101) plane deviated from the normal position. In addition, in the measurement of the relative density and the specific electrical resistance value, the relative density was 88.6% and the specific electrical resistance value was 6 Ω·cm, meaning that the characteristics did not satisfy the conditions of a relative density of 90% or more and a specific electrical resistance of 1 Ω·cm or less. Table 4-1, Table 4-2, and Table 4-3 show the results.

### Comparative Example 6

A Sn—Zn—O-based oxide sintered body according to Comparative Example 6 was obtained in the same way as Example 1 except that the retention time for sintering at 1400° C. was 8 hours.

When X-ray diffraction analysis was carried out on the Sn—Zn—O-based oxide sintered body according to Comparative Example 6, the diffraction peaks of only the Zn₂SnO₄ phase of a spinel type crystal structure and the SnO₂ phase of a rutile-type crystal structure were measured, and the diffraction peaks of different compound phases were not measured. However, the diffraction peak position of the Zn₂SnO₄ (311) plane was 34.33 degrees and the diffraction peak position of the SnO₂ (101) plane was 33.83 degrees, meaning that the diffraction peak position of the SnO₂ (101) plane deviated from the normal position. In addition, in the measurement of the relative density and the specific electrical resistance value, the relative density was 80.6% and the specific electrical resistance value was 800000 Ω·cm, meaning that the characteristics did not satisfy the conditions of a relative density of 90% or more and a specific electrical resistance of 1 Ω·cm or less. Table 4-1, Table 4-2, and Table 4-3 show the results.

### Comparative Example 7

A Sn—Zn—O-based oxide sintered body according to Comparative Example 7 was obtained in the same way as Example 1 except that the formulation was carried out so that the second additional element X would have an atomic ratio of Ta/(Sn+Zn+Bi+Ta) being 0.00009.

When X-ray diffraction analysis was carried out on the Sn—Zn—O-based oxide sintered body according to Comparative Example 7, the diffraction peaks of only the Zn₂SnO₄ phase of a spinel type crystal structure and the SnO₂ phase of a rutile-type crystal structure were measured, and the diffraction peaks of different compound phases were not measured. However, the diffraction peak position of the Zn₂SnO₄ (311) plane was 34.30 degrees and the diffraction peak position of the SnO₂ (101) plane was 33.84 degrees, meaning that both the Zn₂SnO₄ (311) plane and the SnO₂ (101) plane deviated from the normal diffraction peak positions. In addition, in the measurement of the relative density and the specific electrical resistance value, the relative density was 98.3% and the specific electrical resistance value was 120 Ω·cm, meaning that the characteristics satisfied the condition of a relative density of 90% or more but the characteristics did not satisfy the condition of a specific electrical resistance of 1 Ω·cm or less. Table 4-1, Table 4-2, and Table 4-3 show the results.

### Comparative Example 8

A Sn—Zn—O-based oxide sintered body according to Comparative Example 8 was obtained in the same way as Example 1 except that the formulation was carried out so that the second additional element X would have an atomic ratio of Ta/(Sn+Zn+Bi+Ta) being 0.15.

Then, when X-ray diffraction analysis was carried out on the Sn—Zn—O-based oxide sintered body according to Comparative Example 8, the diffraction peak position of the Zn₂SnO₄ (311) plane was 34.37 degrees and the diffraction peak position of the SnO₂ (101) plane was 33.88 degrees, both of which were the normal diffraction peak positions. However, a diffraction peak of the Ta₂O₅ phase was measured in addition to the Zn₂SnO₄ phase of a spinel type crystal structure and the SnO₂ phase of a rutile-type crystal structure. In addition, in the measurement of the relative density and the specific electrical resistance value, the relative density was 94.4% and the specific electrical resistance value was 86 Ω·cm, meaning that the characteristics satisfied the condition of a relative density of 90% or more but the characteristics did not satisfy the condition of a specific electrical resistance of 1 Ω·cm or less. Table 4-1, Table 4-2, and Table 4-3 show the results.

### Comparative Example 9

A Sn—Zn—O-based oxide sintered body according to Comparative Example 9 was obtained in the same way as Example 1 except that the formulation was carried out so that the first additional element M would have an atomic ratio of Bi/(Sn+Zn+Bi+Ta) being 0.00009.

When X-ray diffraction analysis was carried out on the Sn—Zn—O-based oxide sintered body according to Comparative Example 9, the diffraction peaks of only the Zn₂SnO₄ phase of a spinel type crystal structure and the SnO₂ phase of a rutile-type crystal structure were measured, and the diffraction peaks of different compound phases were not measured. However, the diffraction peak position of the Zn₂SnO₄ (311) plane was 34.26 degrees and the diffraction peak position of the SnO₂ (101) plane was 33.85 degrees, meaning that both the Zn₂SnO₄ (311) plane and the SnO₂ (101) plane deviated from the normal diffraction peak positions. In addition, in the measurement of the relative density and the specific electrical resistance value, the relative density was 86.7% and the specific electrical resistance value was 0.13 Ω·cm, meaning that the characteristics satisfied the condition of a specific electrical resistance of 1 Ω·cm or less but the characteristics did not satisfy the condition of a relative density of 90% or more. Table 4-1, Table 4-2, and Table 4-3 show the results.

### Comparative Example 10

A Sn—Zn—O-based oxide sintered body according to Comparative Example 10 was obtained in the same way as Example 1 except that the formulation was carried out so that the first additional element M would have an atomic ratio of Bi/(Sn+Zn+Bi+Ta) being 0.05.

Then, when X-ray diffraction analysis was carried out on the Sn—Zn—O-based oxide sintered body according to Comparative Example 10, the diffraction peak position of the Zn₂SnO₄ (311) plane was 34.36 degrees and the diffraction peak position of the SnO₂ (101) plane was 33.89 degrees, both of which were the normal diffraction peak positions. However, a diffraction peak of other unidentifiable compound phase was measured in addition to the Zn₂SnO₄ phase of a spinel type crystal structure and the SnO₂ phase of a rutile-type crystal structure. In addition, in the measurement of the relative density and the specific electrical resistance value, the relative density was 97.2% and the specific electrical resistance value was 4700 Ω·cm, meaning that the characteristics satisfied the condition of a relative density of 90% or more but the characteristics did not satisfy the condition of a specific electrical resistance of 1 Ω·cm or less. Table 4-1, Table 4-2, and Table 4-3 show the results.

TABLE 4-1

| | First | Second | | | |
|---|---|---|---|---|---|
| | Additional | Additional | Atomic Ratio | | |
| | Element M | Element X | Sn/(Sn + Zn) | M/(Sn + Zn + M + X) | X/Sn + Zn + M + X) |
| Comparative | Bi₂O₃ | Ta₂O₅ | 0.05 | 0.001 | 0.001 |
| Example 1 | | | | | |
| Comparative | Bi₂O₃ | Ta₂O₅ | 0.95 | 0.001 | 0.001 |
| Example 2 | | | | | |
| Comparative | Bi₂O₃ | Ta₂O₅ | 0.5 | 0.001 | 0.001 |
| Example 3 | | | | | |
| Comparative | Bi₂O₃ | Ta₂O₅ | 0.5 | 0.001 | 0.001 |
| Example 4 | | | | | |
| Comparative | Bi₂O₃ | Ta₂O₅ | 0.5 | 0.001 | 0.001 |
| Example 5 | | | | | |
| Comparative | Bi₂O₃ | Ta₂O₅ | 0.5 | 0.001 | 0.001 |
| Example 6 | | | | | |
| Comparative | Bi₂O₃ | Ta₂O₅ | 0.5 | 0.001 | 0.00009 |
| Example 7 | | | | | |
| Comparative | Bi₂O₃ | Ta₂O₅ | 0.5 | 0.001 | 0.15 |
| Example 8 | | | | | |
| Comparative | Bi₂O₃ | Ta₂O₅ | 0.5 | 0.00009 | 0.001 |
| Example 9 | | | | | |
| Comparative | Bi₂O₃ | Ta₂O₅ | 0.5 | 0.05 | 0.001 |
| Example 10 | | | | | |

TABLE 4-2

| | | | | | Specific |
|---|---|---|---|---|---|
| | Sintering | Reten- | Oxygen | | Electrical |
| | Temper- | tion | Concen- | Relative | Resistance |
| | ature | Time | tration | Density | Value |
| | (° C.) | (Hours) | (% by Volume) | (%) | (Ω · cm) |
| Comparative | 1400 | 15 | 80 | 88.0 | 500 |
| Example 1 | | | | | |
| Comparative | 1400 | 15 | 80 | 86.0 | 700 |
| Example 2 | | | | | |
| Comparative | 1400 | 15 | 68 | 87.3 | 53000 |
| Example 3 | | | | | |
| Comparative | 1170 | 15 | 80 | 82.2 | 61000 |
| Example 4 | | | | | |
| Comparative | 1500 | 15 | 80 | 88.6 | 6 |
| Example 5 | | | | | |
| Comparative | 1400 | 8 | 80 | 80.6 | 800000 |
| Example 6 | | | | | |
| Comparative | 1400 | 15 | 80 | 98.3 | 120 |
| Example 7 | | | | | |
| Comparative | 1400 | 15 | 80 | 94.4 | 86 |
| Example 8 | | | | | |
| Comparative | 1400 | 15 | 80 | 86.7 | 0.13 |
| Example 9 | | | | | |
| Comparative | 1400 | 15 | 80 | 97.2 | 4700 |
| Example 10 | | | | | |

TABLE 4-3
X-Ray Diffraction Peak Position (Degrees)

| | ZnO (101) | Zn2SnO4 (311) | SnO2 (101) |
|---|---|---|---|
| Comparative | 36.24 | 34.33 | — |
| Example 1 | | | |
| Comparative | — | 34.33 | 33.92 |
| Example 2 | | | |
| Comparative | — | 34.39 | 33.93 |
| Example 3 | | | |
| Comparative | — | 34.29 | 33.88 |
| Example 4 | | | |
| Comparative | — | 34.34 | 33.95 |
| Example 5 | | | |
| Comparative | — | 34.33 | 33.83 |
| Example 6 | | | |
| Comparative | — | 34.30 | 33.84 |
| Example 7 | | | |
| Comparative | — | 34.37 | 33.88 |
| Example 8 | | | |
| Comparative | — | 34.26 | 33.85 |
| Example 9 | | | |
| Comparative | — | 34.36 | 33.89 |
| Example 10 | | | |

### POSSIBILITY OF INDUSTRIAL APPLICATION

The Sn—Zn—O-based oxide sintered body according to the present invention has characteristics such as a high density and a low resistance in addition to a mechanical strength, and thus has industrial applicability where it is applied to a sputtering target for forming a transparent electrode such as a solar cell and a touch panel.

1: A Sn—Zn—O-based oxide sintered body comprising Zn and Sn as main components, wherein
Sn is contained with an atomic ratio of Sn/(Sn+Zn) being 0.1 or more and 0.33 or less,
a first additional element M is contained with an atomic ratio of M/(Sn+Zn+M+X) being 0.0001 or more and 0.04 or less relative to a total amount of all the metal elements, and
a second additional element X is contained with an atomic ratio of X/(Sn+Zn+M+X) being 0.0001 or more and 0.1 or less relative to the total amount of all the metal elements, where
the first additional element M is at least one selected from Si, Ti, Ge, In, Bi, Ce, Al, and Ga, and
the second additional element X is at least one selected from Nb, Ta, W, and Mo,
a relative density of the sintered body is 90% or more and a specific electrical resistance of the sintered body is 1 Ω·cm or less, and
an X-ray diffraction peak position of the (101) plane of a ZnO phase is 36.25 degrees to 36.31 degrees, and an X-ray diffraction peak position of the (311) plane of a Zn₂SnO₄ phase is 34.32 degrees to 34.42 degrees, as measured by X-ray diffraction using the CuKα radiation.

2. (canceled)

3: A Sn—Zn—O-based oxide sintered body comprising Zn and Sn as main components, wherein
Sn is contained with an atomic ratio of Sn/(Sn+Zn) being more than 0.33 and 0.9 or less,
a first additional element M is contained with an atomic ratio of M/(Sn+Zn+M+X) being 0.0001 or more and 0.04 or less relative to a total amount of all the metal elements, and
a second additional element X is contained with an atomic ratio of X/(Sn+Zn+M+X) being 0.0001 or more and 0.1 or less relative to the total amount of all the metal elements, where
the first additional element M is at least one selected from Si, Ti, Ge, In, Bi, Ce, Al, and Ga, and
the second additional element X is at least one selected from Nb, Ta, W, and Mo,
a relative density of the sintered body is 90% or more and a specific electrical resistance of the sintered body is 1 Ω·cm or less, and
an X-ray diffraction peak position of the (311) plane of a Zn₂SnO₄ phase is 34.32 degrees to 34.42 degrees, and an X-ray diffraction peak position of the (101) plane of a SnO₂ phase is 33.86 degrees to 33.91 degrees, as measured by X-ray diffraction using the CuKα radiation.

4: A method for producing a Sn—Zn—O-based oxide sintered body according to claim 1, wherein the method comprises:
a granulated powder production step of producing a granulated powder by drying a slurry obtained by mixing a ZnO powder, a SnO₂ powder, an oxide powder containing at least one first additional element M selected from Si, Ti, Ge, In, Bi, Ce, Al, and Ga, and an oxide powder containing at least one second additional element X selected from Nb, Ta, W, and Mo, with pure water, an organic binder, and a dispersing agent, followed by granulation;
a compact production step of obtaining a compact by pressing the granulated powder; and
a sintered body production step of obtaining a sintered body by sintering the compact inside a sintering furnace in an atmosphere with an oxygen concentration of 70% by volume or more under conditions of 1200° C. or more and 1450° C. or less and 10 hours or more and 30 hours or less.

5: A method for producing a Sn—Zn—O-based oxide sintered body according to claim 3, wherein the method comprises:
a granulated powder production step of producing a granulated powder by drying a slurry obtained by mixing a ZnO powder, a SnO₂ powder, an oxide powder containing at least one first additional element M selected from Si, Ti, Ge, In, Bi, Ce, Al, and Ga, and an oxide powder containing at least one second additional element X selected from Nb, Ta, W, and Mo, with pure water, an organic binder, and a dispersing agent, followed by granulation;
a compact production step of obtaining a compact by pressing the granulated powder; and
a sintered body production step of obtaining a sintered body by sintering the compact inside a sintering furnace in an atmosphere with an oxygen concentration of 70% by volume or more under conditions of 1200° C. or more and 1450° C. or less and 10 hours or more and 30 hours or less.
